(19) United States
(12) Patent Application Publication
(10) Pub. No.: US 2019/0229734 A1
(43) Pub. Date: Jul. 25, 2019

(54) VERTICAL RESISTOR BUFFERED MULTIPLEXER BUSKEEPER

(71) Applicant: Microsemi SoC Corp., San Jose, CA (US)

(72) Inventors: Volker Hecht, Barsinghausen (DE); John L. McCollum, Orem, UT (US)

(73) Assignee: Microsemi SoC Corp., San Jose, CA (US)

(21) Appl. No.: 16/249,733

(22) Filed: Jan. 16, 2019

Related U.S. Application Data
(60) Provisional application No. 62/642,415, filed on Mar. 13, 2018.
(60) Provisional application No. 62/621,469, filed on Jan. 24, 2018.

(51) Int. Cl. H03K 19/177; H01L 23/50

(52) U.S. Cl. CPC H03K 19/17744; H01L 23/50

(57) ABSTRACT

A buffered multiplexer includes a multiplexer having N multiplexer inputs each input selectively coupleable to a single multiplexer output. A non-inverting buffer has an input coupled to the multiplexer output and an output forming the output node of the buffered multiplexer. At least one vertical resistor is coupled between the input and the output of the non-inverting buffer.

### BACKGROUND

Multiplexers are widely used circuit elements in integrated circuits. In particular multiplexers are included in user-configurable integrated circuits such as field programmable gate array integrated circuits as well as other types of user-configurable integrated circuits.

When a number of multiplexers are provided on user-configurable integrated circuits, there is a significant likelihood that not all of them will be incorporated into a user design programmed into the integrated circuit. Where one or more multiplexers remains unused in a user design programmed into the integrated circuit provision must be made to assure that the outputs of the multiplexers are tied to one of the logic levels in the circuit, such as VDD or VSS.

Referring now to FIG. 1A, a schematic diagram shows an N-input buffered multiplexer 10 having a multiplexer portion 12 and a non-inverting buffer portion 14. Multiplexer portion 12 includes inputs inl (shown at reference numeral 16) through inN (shown at reference numeral 18). Each input may be selectively coupled to an intermediate node 20 responsive to a respective configuration circuit CFG₁ through CFG_{N} (shown at reference numerals 24-1 to 24-N). In the multiplexer portion 12 of FIG. 1A, CMOS passgate 22-1 is enabled to pass a logic level representing the data bit at input inl (16) to the intermediate node 20 by enabling the configuration circuit 24-1 associated with the in1 (16) select input of the multiplexer portion 12 Similarly, CMOS passgate 22-N is enabled to pass the data bit at input inN to the intermediate node 20 by enabling its configuration circuit 24-N.

Intermediate node 20 is coupled to the input of the non-inverting buffer portion 14, shown in FIG. 1A as two series connected inverters 26 and 28, driving an output node 30.

When none of inputs in1 (16) through inN (18) are being used, the intermediate node 20 of the multiplexer portion 12 will be left floating in an undetermined state which may be at an intermediate voltage between VDD and VSS. This can cause the non-inverting buffer portion 14 to operate in an analog voltage region somewhere between VDD and VSS. If this happens, excess current will be drawn that can damage or destroy the integrated circuit device.

In order to prevent the intermediate node 20 of the multiplexer portion 12 from being left floating in an undetermined state which may be at an intermediate voltage between VDD and VSS, the prior art has provided several solutions. The solution shown in FIG. 1A is to provide an additional input 32 to the multiplexer portion 12. Input 32 may be referred to as a tie-off input and is used to tie off the intermediate node 20 to either VDD or VSS provided at input 32 to prevent floating input leakage at the non-inverting buffer portion 14 by turning on CMOS passgate 22-to by enabling its configuration circuit 24-to to pass either VDD or VSS provided at input 32 to the intermediate node 20 when none of the other inputs are selected.

Referring now to FIG. 1B, a similar buffered multiplexer 40 is depicted. Because buffered multiplexer 40 is very similar to buffered multiplexer 10 of FIG. 1, having many of the same elements, like reference numerals will be used for convenience to designate like elements in the two drawing figures.

The difference between buffered multiplexers 10 and 40 is that multiplexer portion 12′ of buffered multiplexer 40 employs n-channel transistors 42-1 through 42-N to select which of inputs 16 through 18 will be passed to intermediate node 20. The solution shown in FIG. 1B to the issue of when none of inputs in1 (16) through inN (18) are being used, the intermediate node 20 of the multiplexer portion 12 is left floating in an undetermined state, is to also provide an additional input 32 to the multiplexer portion 12′. As in buffered multiplexer 10 of FIG. 1A, buffered multiplexer 40 of FIG. 1B includes an additional tie-off input 32 that is used to tie off the intermediate node 20 to either VDD or VSS provided at input 32 by turning on n-channel transistor 42-to by enabling its configuration circuit 24-to to pass either VDD or VSS provided at input 32 to the intermediate node 20 when none of the other inputs are selected.

While the buffered multiplexers of FIGS. 1A and 1B perform the function of preventing the output node of the multiplexer portion 12, 12′ from assuming an unknown state when none of its data inputs are selected, both do so at the cost of including an extra switch (CMOS passgate or n-channel transistor), and an extra configuration cell 24-to.

Referring now to FIG. 2, another prior-art buffered multiplexer 50 is depicted. Because buffered multiplexer 50 is also very similar to buffered multiplexer 10 of FIG. 1A and buffered multiplexer 40 of FIG. 1B, having many of the same elements, like reference numerals will be used for convenience to designate like elements in the three drawing figures.

N-input buffered multiplexer 50 includes a multiplexer portion 12 that has inputs in1 (shown at reference numeral 16) through inN (shown at reference numeral 18). Each input may be selectively coupled to an intermediate node 20. In the multiplexer portion 12 of FIG. 2, either CMOS passgates or n-channel pass transistors may be employed and are enabled as in FIGS. 1A and 1B to pass the data bit at one of inputs in1 through inN to the intermediate node 20 by enabling its respective configuration circuit 24-1 through 24-N. Intermediate node 20 is coupled to a non-inverting buffer portion 14, shown in FIG. 2 as two series connected inverters 26 and 28, driving an output node 30.

Buffered multiplexer 50 employs a weak inverter 52 as a buskeeper in a feedback loop in the non-inverting buffer portion 14, weak inverter 52 having its input connected to the output of inverter 28 and its output connected to the input of inverter 26. Weak inverter 52 keeps the input of inverter 26 at either VDD or VSS if none of inputs in1 (16) through inN (18) are passed through multiplexer buffered multiplexer 50. Weak inverter 52 is sized to be weak enough so that a signal at intermediate node 20 of multiplexer portion 12 can easily overdrive the output of inverter 52 and force the input of inverter 26 to the logic state of the selected one of inputs in1 (16) through inN (18).

Although the buffered multiplexer 50 offers a savings of the extra pass device and configuration input over the multiplexers 10 and 40 of FIGS. 1A and 1B, it does so at the cost of the additional two transistors needed to form the weak inverter 52 as a bus-keeper inverter. Also, the respective driver of intermediate node 20 of the multiplexer portion 12 has to overcome the state of the weak inverter 52 which thus adds some measure of delay from input to output of the buffered multiplexer 50.

### BRIEF DESCRIPTION

In accordance with one aspect of the present invention, a buffered multiplexer includes a multiplexer portion having N multiplexer inputs each input selectively coupleable to a single multiplexer output. A non-inverting buffer has an input coupled to the multiplexer portion output and an output forming the output node of the buffered multiplexer. At least one vertical resistor is coupled between the input and the output of the non-inverting buffer.

According to another aspect of the present invention, the at least one vertical resistor includes a first vertical resistor connected in series with a second vertical resistor coupled between the input and the output of the non-inverting buffer.

According to another aspect of the present invention, the at least one vertical resistor includes a first pair of vertical resistors connected in parallel, and a second pair of vertical resistors connected in parallel. The first pair of vertical resistors and the second pair of vertical resistors are connected in series and coupled between the input and the output of the non-inverting buffer.

According to another aspect of the invention the vertical resistor(s) may be formed from several different structures, including antifuse structures, “virgin” ReRAM devices, and other high resistance material layers.

According to another aspect of the present invention, the non-inverting buffer includes a first inverter connected in series with a second inverter.

### BRIEF DESCRIPTION OF THE DRAWING FIGURES

The invention will be explained in more detail in the following with reference to embodiments and to the drawing in which are shown:

FIG. 1A is a schematic diagram of a prior-art buffered multiplexer employing CMOS passgates as switches;

FIG. 1B is a schematic diagram of a prior-art buffered multiplexer employing re-channel transistors as switches;

FIG. 2 is a schematic diagram of prior-art buffered multiplexer including a weak inverter employed as a buskeeper;

FIG. 3 is a schematic diagram of a buffered multiplexer including a vertical resistor as a buskeeper in accordance with an aspect of the present invention;

FIG. 4 is a schematic diagram of a buffered multiplexer including two vertical resistors as a buskeeper in accordance with an aspect of the present invention;

FIG. 5 is a schematic diagram of a buffered multiplexer including four vertical resistors as a buskeeper in accordance with an aspect of the present invention;

FIG. 6 is a cross-sectional view of a typical antifuse device structure that may be employed as a vertical resistor in embodiments of the present invention;

FIG. 7 is a cross-sectional view of a typical virgin ReRAM device structure that may be employed as a vertical resistor in embodiments of the present invention; and

FIG. 8 is a cross-sectional view of another typical high-resistance structure that may be employed as a vertical resistor in embodiments of the present invention.

### DETAILED DESCRIPTION

Persons of ordinary skill in the art will realize that the following description of the present invention is illustrative only and not in any way limiting. Other embodiments of the invention will readily suggest themselves to such skilled persons.

Referring now to FIG. 3, a schematic diagram shows a buffered multiplexer 60 in accordance with the present invention. Elements of the buffered multiplexer 60 that are found in the preceding drawing figures will be designated using the same reference numerals used to designate those elements in the preceding drawing figures.

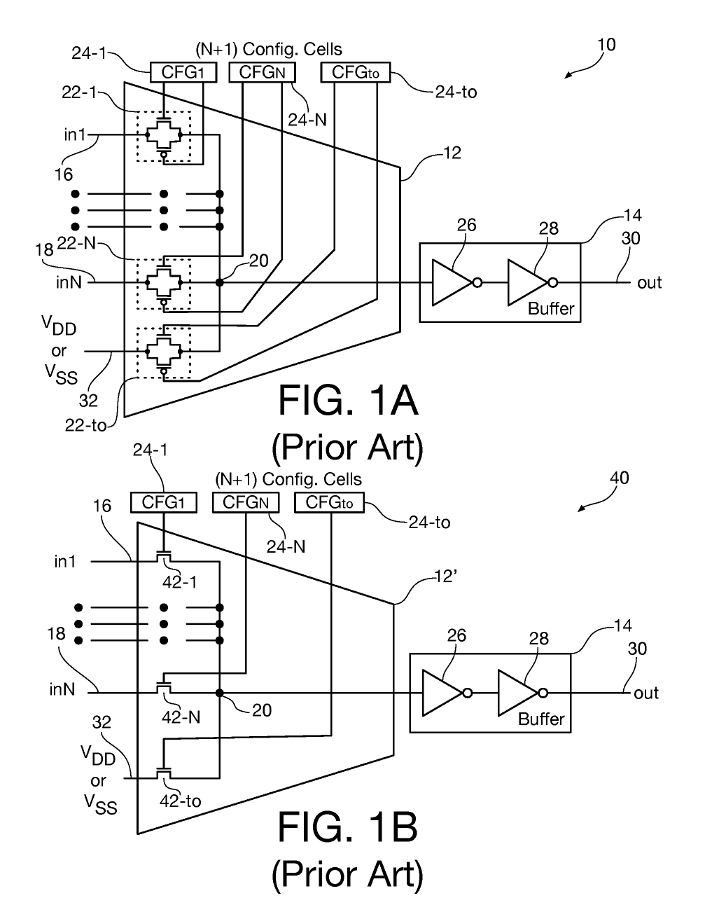

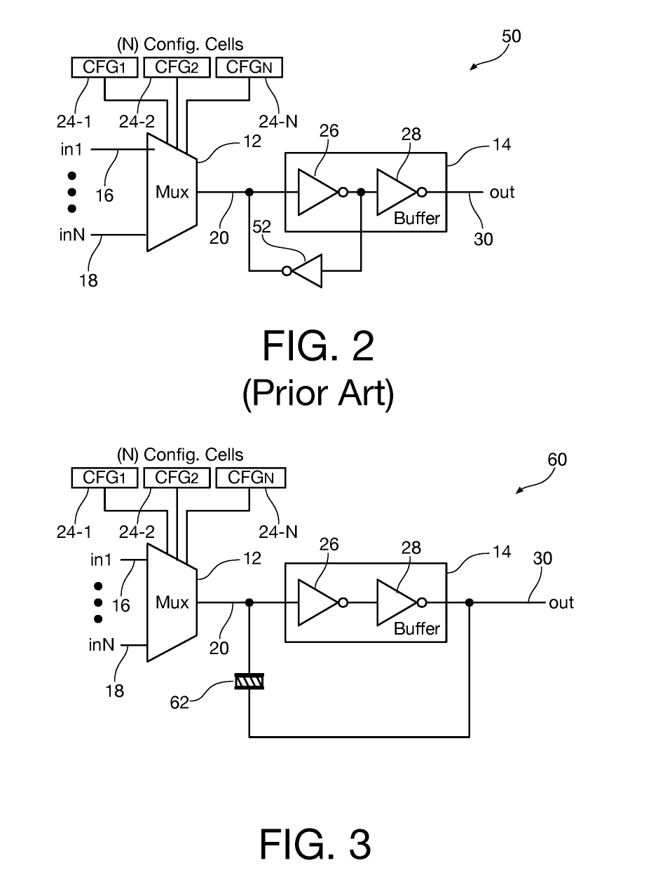

N-input buffered multiplexer 60 has a multiplexer portion 12 including inputs inl (shown at reference numeral 16) through inN (shown at reference numeral 18). Each input may be selectively coupled to an output node 20. In the buffered multiplexer 60 of FIG. 3, either CMOS passgates or n-channel pass transistors can be used as the switch elements and may be enabled as in FIGS. 1A and 1B to pass the data bit at one of inputs inl (16) through inN (18) to the intermediate node 20 by enabling its respective configuration circuit 24-1 through 24-N. Intermediate node 20 is coupled to a non-inverting buffer portion 14 of the buffered multiplexer 60, shown in FIG. 2 as two series connected inverters 26 and 28, driving an output node 30.

The buffered multiplexer 60 employs a vertical resistor shown at reference numeral 62 as a buskeeper. Vertical resistor 62 is connected between the output of non-inverting buffer portion 14 (the output of inverter 28) and its input (the input of inverter 26).

Vertical resistor 62 is a high resistance value-resistor, typically having a resistance in a range from about 1M ohm to greater than about 1G ohm. As will be disclosed herein, vertical resistor 62 may take any one of several forms. The symbol shown at reference numeral 62 is used throughout to designate the vertical resistor and will be used to designate all of the several forms taken by the vertical resistor. The operation of the vertical resistor 62 in providing the buskeeping function to the buffered multiplexer 60 will be disclosed herein.

The vertical resistor 62 has a resistance that is low enough to act as a buskeeper by forcing the intermediate node 20, i.e. the output of the multiplexer portion 12 of the buffered multiplexer 60, at the input of non-inverting buffer portion 14 to assume the state of the output of the inverter 28 at the output of the non-inverting buffer portion 14 but high enough to prevent a time delay impact on the speed of the multiplexer portion 12 when the signal passed through from one of its inputs to intermediate node 20 has to force the input of inverter 26 to a desired logic level. This is also aided by the fact that the vertical resistor 62 has a very low capacitance.

The buffered multiplexer of FIG. 3 has several advantages over the prior art. For a multiplexer having N inputs, only N configuration circuits are required. No extra transistors are required and the vertical resistor 62 occupies the size of a typical metal-to-metal via in the integrated circuit and thus wastes negligible layout area. This results in a savings of one multiplexer input (amounting to one or two transistors) and one configuration circuit (amounting to several transistors).

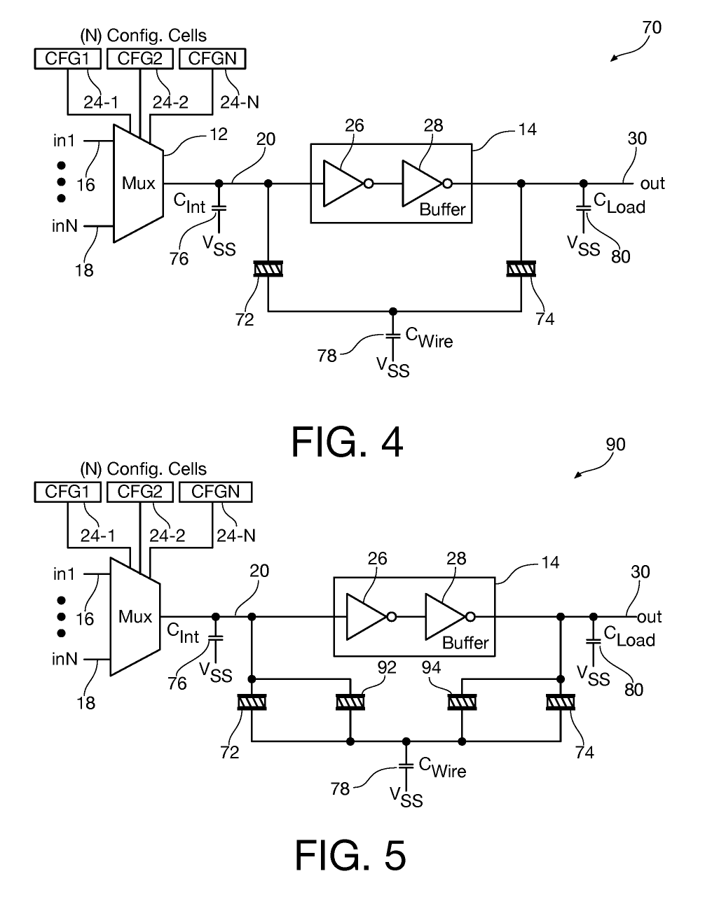

Referring now to FIG. 4, a schematic diagram shows a buffered multiplexer 70 including two vertical resistors configured as a buskeeper in accordance with an aspect of the present invention. Elements of the buffered multiplexer 70 that are found in the preceding drawing figures will be designated using the same reference numerals used to designate those elements in the preceding drawing figures.

N-input buffered multiplexer 70 includes a multiplexer portion 12 and a non-inverting buffer portion 14. The multiplexer portion 12 has inputs inl (shown at reference numeral 16) through inN (shown at reference numeral 18). Each input may be selectively coupled to an intermediate node 20, i.e. the output of the multiplexer portion 12. In the buffered multiplexer 70 of FIG. 4, either CMOS passgates or n-channel pass transistors can be used as the switch elements for the multiplexer portion 12, and may be enabled as shown in the preceding drawing figures to pass the data bit at one of inputs inl through inN to the intermediate node 20 by enabling its configuration circuit 24-1 through 24-N. Intermediate node 20 is coupled to the non-inverting buffer portion 14 of buffered mutiplexer 70, shown in FIG. 4 as two series connected inverters 26 and 28, driving an output node 30.

The buffered multiplexer 70 employs two vertical resistors 72 and 74 that act together as a buskeeper. Vertical resistors 72 and 74 are connected in series between the output of the non-inverting buffer portion 14 (the output of inverter 28) and its input (the input of inverter 26). It has the same advantages as the single vertical resistor bus-keeper 60 of FIG. 3. In addition, it prevents delay impact at buffer outputs from the capacitance of the wire segment Cwire (reference numeral 78) used to connect it to the circuit because Cwire is hidden on both sides behind the high resistance of vertical resistors 72 and 74.

The capacitance effects of the two-vertical-resistor buskeeper circuit can be expressed as:

Rvres*Cwire>>Rmux*Cint, Rvres*Cwire>>Rbuf*Cload

Where Rvres is the resistance of a single vertical resistor 72, 74, respectively, Cwire (reference numeral 78) is the capacitance of the connections for the vertical resistors 72 and 74, Rmux is the internal resistance of the multiplexer portion 12 as seen at intermediate node 20, Cint (reference numeral 76) is the internal capacitance of the multiplexer portion 12 as seen at intermediate node 20, and Cload (reference numeral 80) is the capacitance of the load connected to the buffered multiplexer 70 seen by output node 30.

The arrangement of two vertical resistors 72 and 74 also provides serial redundancy in that it tolerates what would be a defect caused by one of the vertical resistors 72 or 74 having too low a resistance.

FIG. 5 is a schematic diagram of a buffered multiplexer 90 including four vertical resistors configured as a buskeeper in accordance with an aspect of the present invention. The buffered multiplexer 90 of FIG. 5 operates in exactly the same manner as the buffered multiplexer 70 of FIG. 4 except that the arrangement of four vertical resistors configured as a buskeeper provides additional advantages.

The arrangement of four vertical resistors connected between the output and the input of the non-inverting buffer portion 14 of buffered multiplexer 90, where vertical resistor 72 is connected in parallel with vertical resistor 92, and vertical resistor 74 is connected in parallel with vertical resistor 94, and these parallel combinations are connected in series as shown in FIG. 5. Like the arrangement of vertical resistors 72 and 74 in FIG. 4, the arrangement of vertical resistors in FIG. 5 also provides serial redundancy in that it tolerates what would be a defect caused by either one of the vertical resistors 72 or 92 or either one of the vertical resistors 74 or 94 having too low a resistance.

The arrangement of vertical resistors in FIG. 5 also provides parallel redundancy in that it tolerates what would be a defect caused by any one of the vertical resistors in a parallel pair (i.e., one of vertical resistors 72 or 92 or one of vertical resistors 74 or 94) having too high a resistance.

Both of the solutions shown in FIGS. 4 and 5 will take up slightly more layout area that the single vertical resistor buskeeper of FIG. 3, but this will be much less area than any of the prior-art solutions.

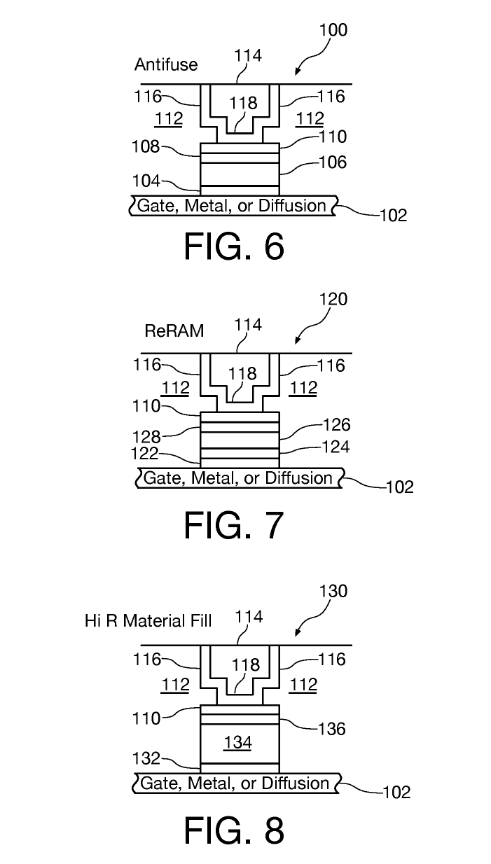

Referring now to FIG. 6, a cross-sectional view shows a typical unprogrammed antifuse device structure 100 that may be employed as one form of a vertical resistor in embodiments of the present invention. The unprogrammed antifuse 100 is formed over one of a transistor gate, metal interconnect layer, or diffusion in a substrate or well (shown as layer 102). Layer 104 is a lower electrode of the antifuse, layer 106 is a layer of antifuse material formed over the lower electrode 104 and which may be formed from a material such as doped or undoped amorphous silicon. An upper electrode 108 is formed over the antifuse material 106. The layers 104, 106, and 108 may then be etched as a stack. In some embodiments, layer 102 may be used as an etch stop layer and in other embodiments a separate etch-stop layer (not shown) may be formed over layer 102. In some embodiments, an additional diffusion barrier layer 110 for an upper layer of metal is also formed on and etched with the stack.

A dielectric layer 112 is then formed over the stack of layers 104, 106, and 108 and a metal layer is formed and connected to the top layer (110 or 108) of the stack. In FIG. 6, the metal layer is shown as a damascene copper layer 114 surrounded by a liner 116 as is known in the art. Prior to formation of the liner 116 and the copper metal line 114, a via 118 is formed to make connection to the top layer 108 or 110 of the antifuse device structure 100 as is known in the art.

Antifuse structures such as the one described above are well known. One non-limiting illustrative example of an antifuse device structure 100 is shown in U.S. Pat. No. 5,770,885, the entire contents of which are incorporated herein by reference. The antifuse 100 remains unprogrammed, and in this state has a resistance on the order of from about 1M ohm to more than 1G ohms.

Referring now to FIG. 7, a cross-sectional view shows a typical virgin ReRAM device structure 120 that may be employed as another form of a vertical resistor in embodiments of the present invention. A “virgin” ReRAM device 120, is identical in every way to a conventional ReRAM device except there is no way to program or erase it so it always remains in the fully erased state in which it was when fabricated. This is a high impedance state, where its resistance is field dependent but is greater than about 10MΩ and generally about 1GΩ. This form of a vertical resistor, implemented as virgin ReRAM device structure 120 is very useful in that it provides an extremely high impedance while taking up almost no layout area on the integrated circuit because it can be fabricated on an existing contact or inter-metal via in the integrated circuit structure. The polarity of the ReRAM device structure 120 does not matter. One non-limiting example of a ReRAM device is described in U.S. Pat. No. 8,415,650 issued Apr. 9, 2013, the entire contents of which are incorporated herein by reference. The ReRAM device structure 120 remains unprogrammed.

As shown in FIG. 7 to which attention is now directed, a ReRAM device is basically two metal plates separated by a solid electrolyte layer. The ReRAM device normally can be programmed by applying a voltage potential having a polarity that will drive metal ions from one of the metal plates into the solid electrolyte layer and erased by applying a voltage potential having a polarity that will drive the metal ions back to the source metal plate.

Some of the structure shown in the embodiment of FIG. 8 is similar to some of the structure depicted in FIG. 7. Accordingly, elements present in FIG. 8 that correspond to elements in FIG. 7 will be designated using the same reference numerals as used in FIG. 7.

An unprogrammed (“virgin”) ReRAM device 120 is formed over one of a transistor gate, metal interconnect layer, or diffusion in a substrate or well (shown as layer 102). Layer 102 is a diffusion barrier and/or adhesion layer. Layer 122 is a barrier layer. Layer 124 is a lower electrode of the virgin ReRAM device 120. Layer 126 is a solid electrolyte layer formed over the lower electrode 124. An upper electrode 128 is formed over the solid electrolyte layer 136. In some embodiments, a diffusion barrier layer 110 is also formed on and etched with the stack. The layers 122, 124, 126, 128, and 110 (if present) may then be etched as a stack. In some embodiments, layer 102 may be used as an etch stop layer and in other embodiments a separate etch-stop layer (not shown) may be formed over layer 102.

As in the embodiment of FIG. 6, a dielectric layer 112 is then formed over the stack of layers 122, 124, 126, 128 and 110 and a metal layer is formed and connected to the top layer (110 or 128) of the stack. In FIG. 7, the metal layer is shown as a damascene copper layer 114 surrounded by a liner 116 as is known in the art. Prior to formation of the liner 116 and the copper metal line 114, a via 118 is formed to make connection to the top layer 128 or 110 of the virgin ReRAM device structure 120 as is known in the art.

Referring now to FIG. 8, a cross-sectional view shows another typical high-resistance structure that may be employed as a vertical resistor in embodiments of the present invention. Some of the structure shown in the embodiment of FIG. 8 is similar to some of the structure depicted in FIG. 6 and FIG. 7 Accordingly, elements present in FIG. 8 that correspond to elements in the embodiments of FIG. 6 and FIG. 7 will be designated using the same reference numerals as used in those drawing figures.

A high-resistance structure 130 is formed over one of a transistor gate, metal interconnect layer, or diffusion in a substrate or well (shown as layer 102). Layer 132 is a diffusion barrier and/or adhesion layer. Layer 134 is layer of high-resistance material formed over layer 132. A second diffusion barrier layer 136 is formed over the layer of high-resistance material 134. In some embodiments, a second diffusion barrier layer 110 is also formed on and etched with the stack. The layers 132, 134, 136, and 110 (if present) may then be etched as a stack. In some embodiments, layer 102 may be used as an etch stop layer and in other embodiments a separate etch-stop layer (not shown) may be formed over layer 102.

As in the embodiment of FIG. 6 and FIG. 7, a dielectric layer 112 is then formed over the stack of layers 132, 134, 136, and 112 and a metal layer is formed and connected to the top layer (110 or 136) of the stack. In FIG. 8, the metal layer is shown as a damascene copper layer 114 surrounded by a liner 116 as is known in the art. Prior to formation of the liner 116 and the copper metal line 114, a via 118 is formed to make connection to the top layer 136 or 110 of the high-resistance structure as is known in the art.

Numerous materials may be employed to form the high-resistance layer 134. A non-exhaustive list includes silicon-rich SiO₂, tantalum-rich Ta₂O₅, titanium-rich TiO₂, aluminum-rich Al₂O₃, silicon-rich SiN. Such films can be formed using CVD, PECVD and other deposition processes. Other process-compatible stable high-resistance materials will readily suggest themselves to persons of ordinary skill in the art. The thicknesses and chemical compositions of these materials and the deposition conditions necessary to deposit them to produce desired values of resistance can be easily determined experimentally for employment in particular embodiments of the present invention. These design parameters are easily tailored by persons of ordinary skill in the art to achieve a resistance value of from about 1M ohm to greater than 1G ohm.

Persons of ordinary skill in the art will appreciate that, while a damascene copper metallization structure is shown in FIGS. 6-8, other types of metallization layers may be employed instead. Such skilled persons will readily understand how to integrate such other metallization schemes into the present invention.

Persons of ordinary skill in the art will appreciate that the drawing figures show the vertical resistors all oriented in the same polarity. Such skilled persons will appreciate that, since the devices will never be programmed, in any of the circuits disclosed herein the orientation of the ReRAM device implementation of the vertical resistor does not matter and they can be oriented in whatever manner best suits the layout and design.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

What is claimed is:

1. A buffered multiplexer comprising:
a multiplexer having N multiplexer inputs each input selectively coupleable to a single multiplexer output;
a non-inverting buffer having an input and an output, the input coupled to the multiplexer output; and
at least one vertical resistor coupled between the input and the output of the non-inverting buffer.

2. The buffered multiplexer of claim 1 wherein the at least one vertical resistor is formed as an unprogrammed antifuse.

3. The buffered multiplexer of claim 1 wherein the at least one vertical resistor is formed as a virgin ReRAM device.

4. The buffered multiplexer of claim 1 wherein the at least one vertical resistor is formed as a layer of a high-resistance metal compound.

5. The buffered multiplexer of claim 1 wherein the non-inverting buffer includes a first inverter connected in series with a second inverter.

6. The buffered multiplexer of claim 1 wherein the at least one vertical resistor comprises a first vertical resistor connected in series with a second vertical resistor coupled between the input and the output of the non-inverting buffer.

7. The buffered multiplexer of claim 6 wherein the first and second vertical resistors are formed as an unprogrammed antifuse.

8. The buffered multiplexer of claim 6 wherein the first and second vertical resistors are formed as a virgin ReRAM device.

9. The buffered multiplexer of claim 6 wherein the first and second vertical resistors are formed as a layer of a high-resistance metal compound.

10. The buffered multiplexer of claim 6 wherein the non-inverting buffer includes a first inverter connected in series with a second inverter.

11. A buffered multiplexer comprising:
a multiplexer having N multiplexer inputs each input selectively coupleable to a single multiplexer output;
a non-inverting buffer having an input and an output, the input coupled to the multiplexer output;
a first parallel circuit including a first pair of vertical resistors connected in parallel, a first end of the first parallel circuit coupled to the output of the non-inverting buffer;
a second parallel circuit including a second pair of vertical resistors connected in parallel, a first end of the second parallel circuit coupled to the input of the non-inverting buffer;
a second end of the first parallel circuit coupled to the second end of the second parallel circuit.

12. The buffered multiplexer of claim 11 wherein the first and second pairs of vertical resistors are formed as an unprogrammed antifuse.

13. The buffered multiplexer of claim 11 wherein the first and second pairs of vertical resistors are formed as a virgin ReRAM device.

14. The buffered multiplexer of claim 11 wherein the first and second vertical resistors are formed as a layer of a high-resistance metal compound.

15. The buffered multiplexer of claim 11 wherein the non-inverting buffer includes a first inverter connected in series with a second inverter.

16. In a multiplexer having a plurality of data inputs selectively coupleable to a data output, a method for preventing the output of the mutiplexer from assuming an undetermined state when none of the data inputs have been selected, the method comprising:
connecting a non-inverting buffer between the data output of the multiplexer and an output node of the multiplexer coupling the output of the non-inverting buffer; and
coupling a vertical resistor between the input of the non-inverting buffer and the output of the non-inverting buffer, the vertical resistor having a resistance that is low enough to force the output of the multiplexer at the input of non-inverting buffer to assume the state of the output of the non-inverting buffer portion, the resistance being high enough to prevent a time delay impact on the speed of the multiplexer when the signal passed through from one of its inputs has to force the input of the non-inverting buffer to a desired logic level.

17. The method of claim 16, wherein coupling a vertical resistor between the input of the non-inverting buffer and the output of the non-inverting buffer comprises coupling one of an unprogrammed antifuse, a virgin ReRAM device, and a high-resistance metal compound between the input of the non-inverting buffer and the output of the non-inverting buffer.
